(19) United States
(12) Patent Application Publication
(10) Pub. No.: US 2025/0112055 A1
(43) Pub. Date: Apr. 3, 2025

(54) ETCHING PROCESSING METHOD AND ETCHING PROCESSING APPARATUS

(71) Applicant: Hitachi High-Tech Corporation, Tokyo (JP)

(72) Inventors: Nobuya MIYOSHI, Hillsboro, OR (US); Nicholas McDowell, Hillsboro, OR (US); Ritchie Scott-McCabe, Hillsboro, OR (US)

(21) Appl. No.: 18/374,224

(22) Filed: Sep. 28, 2023

(51) Int. Cl. H01L 21/311; H01J 37/32; H01L 21/67

(52) U.S. Cl. CPC H01L 21/31105; H01J 37/32449; H01L 21/67115; H01J 2237/332

(57) ABSTRACT

A method of etching an SiCO film on a wafer includes a step of supplying the wafer 8 placed on a wafer stage 9 in a processing chamber 7 inside a vacuum container 11 with an oxygen radical or ozone to form an oxide layer 5 on the surface of the SiCO film 1; a step of generating plasma to form a reactive radical from a gas containing CF, and NH3 and thereby modifying the oxide layer 5 into a surface modified layer 6; a step of eliminating and removing the surface modified layer 6; and conducting the oxide layer 5 formation step, the surface modified layer 6 formation step and the surface modified layer 6 elimination and removal step in repetition to etch the SiCO film 1.

### BACKGROUND OF THE INVENTION

The present invention relates to an etching processing method and an etching processing apparatus of an SiCO (low-k) film.

In the fields of semiconductor devices, in order to satisfy a demand for reducing energy consumption or increasing storage capacity, further miniaturization and development of a 3D device structure are underway in both logic and memory devices. For example, in the logic device, a Fin-type FET (FinFET) is miniaturized to near its limit so that device makers are developing Gate-All-Around (GAA) devices. In the memory device, on the other hand, a 3D NAND flash memory has already become the main stream and further, development of 3D DRAM has energetically been promoted.

The structure of a device having a 3D structure is sterically more complex than that of a device having a 2D structure and for the manufacture of such a device, in addition to vertical (anisotropic) etching performed in a direction vertical to a wafer surface, isotropic etching capable of etching a wafer surface also in a lateral direction is frequently used.

Isotropic etching has conventionally been conducted by wet processing with a chemical liquid, but due to advances in miniaturization, problems such as pattern collapse due to the surface tension of the chemical liquid and an etching residue in a minute space are becoming more apparent. In isotropic etching, therefore, there is a growing tendency to use dry processing without a chemical liquid instead of conventional wet processing with a chemical liquid.

PTL 1 discloses, as one example of isotropic dry etching of a silicon oxide film, a processing method including modifying a silicon oxide surface with an HF gas and an NH₃ gas, then heating a substrate to eliminate and remove the modified layer, and thus removing the silicon oxide film.

Non-PTL 1 discloses, as an isotropic dry etching method of a silicon oxide film, a processing method including modifying the surface with CF₄/NH₃ plasma, then removing the modified layer, and thereby removing the silicon oxide film.

### CITATION LIST

### Patent Literature

PTL 1: JP2020-4837A

### Non Patent Literature

Non-PTL 1: Yegeun Cho et al. “Atomic layer etching of SiO2 for surface cleaning using ammonium fluorosilicate with CF4/NH3 plasma”, Journal of Vacuum Science and Technology A 38, 022604 (2020)

### SUMMARY OF THE INVENTION

For example, in the processing around a gate of a Fin type FET (FinFET) or Gate-All-Around (GAA) device, a technology is expected to be required, which etches an SiCO film, one of low-k materials, isotropically and uniformly both within the surface of a substrate and in the depth direction with atomic-layer-level controllability.

FIG. 1 shows isotropic processing of an SiCO film 1 in a next-generation GAA device, which is one example of the aforesaid technology. The SiCO film 1 is formed to cover an Si nanosheet 2, an SiGe sacrificial layer 3, and even a CMOS gate 4. These gate structures have, at the bottom thereof, a silicon oxide film layer or a silicon substrate. In this etching step, required are isotropic etching of the SiCO film 1 and at the same time, high-precision and uniform control of an etching amount over the entire surface (within the surface of the substrate and in the depth direction) of the 3D structure.

In the conventional wet processing, it is difficult to control the etching amount with high precision and pattern collapse due to the surface tension of a chemical liquid or etching residue in a minute space becomes a problem. In spontaneous etching with a reactive radical, an etching rate of the SiCO film is different between the upper portion and the lower portion of a pattern due to supply rate control of the radical, making it difficult to uniformly process the SiCO film on the pattern.

It has been confirmed in the method shown in PTL 1 that although the silicon oxide film (SiO₂) is etched with an increase in the number of etching processing cycles as shown in FIG. 2, an SiCO film is not etched. Also, the isotropic atomic layer etching method of a silicon oxide film shown in Non-PTL 1 has such a drawback that an etching rate of the SiCO film is very small.

The present invention has been made in consideration of such problems of the prior art and an object of the present invention is to provide an isotropic etching processing method and an etching processing apparatus, each capable of achieving highly-precise control of an etching amount.

An etching processing method according to one embodiment of the present invention is to etch an SiCO film formed on a wafer and it includes repeating the following steps: a step of supplying the wafer placed on a wafer stage in a processing chamber inside a vacuum container with oxygen radical or ozone to oxidize a surface of the SiCO film, a step of supplying the wafer with reactive radical by using plasma to form a modified layer from an oxide layer on the surface of the SiCO film, and a step of eliminating and removing the modified layer.

An etching processing apparatus according to another embodiment of the present invention has a vacuum container having therein a processing chamber and a plasma source provided above the processing chamber, a wafer stage which is provided in the processing chamber and on which a wafer having the SiCO film formed thereon is placed, a first mass flow controller that supplies the plasma source with a processing gas to be used for plasma processing, a heating device for heating the wafer, and a control unit for controlling the etching processing of the SiCO film. In the control unit, the following steps are repeated: a step of introducing, into the plasma source, a gas containing an oxygen whose supply flow rate is adjusted by the first mass flow controller, supplying the wafer with an oxygen radical or ozone generated by causing the plasma source to generate plasma, and thereby oxidizing the surface of the SiCO film; a step of introducing, into the plasma source, a gas containing CF₄ and NH₃ whose supply flow rate is adjusted by the first mass flow controller, supplying the wafer with a reactive radical generated by causing the plasma source to generate plasma, and thereby forming a modified layer on the surface of the SiCO film, and a step of heating the wafer with the heating device to eliminate and remove the modified layer.

The present invention makes it possible to achieve, in isotropic dry etching of an SiCO film, highly-precise control of an etching amount and uniform processing in both wafer surface and depth direction. The problem, constitution, and advantageous effect other than those described above will be apparent from the description of the following embodiments.

### BRIEF DESCRIPTION OF THE DRAWINGS

FIG. 1 is a schematic view of an isotropic etching step of an SiCO film in a GAA device manufacturing process.

FIG. 2 shows the experimental results of the relationship between an etching amount and the number of cycles when an SiO₂ film and an SiCO film are etched by the method disclosed in PTL 1.

FIG. 3 is a schematic view of an etching processing procedure of the present Example.

FIG. 4 shows the dependence of an etching amount on the number of cycles in the etching processing method of the present Example.

FIG. 5 shows the dependence of an etching rate on a surface oxidation time in the etching processing method of the present Example.

FIG. 6 shows the dependence of an etching rate on a surface modification time in the etching processing method of the present Example.

FIG. 7 is a schematic view of an etching processing apparatus.

FIG. 8 is a time sequence of the etching processing method of the present Example.

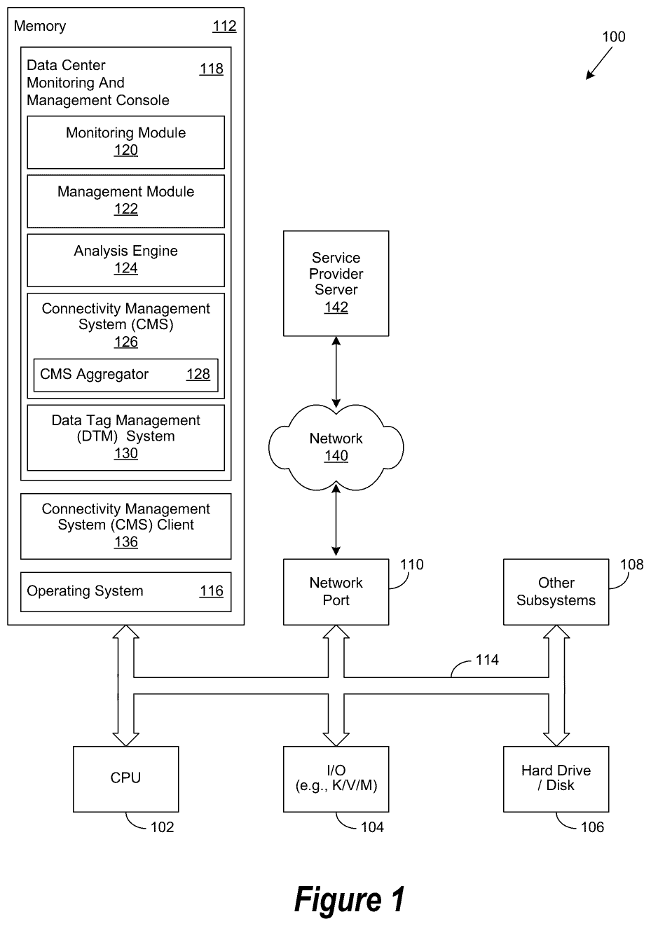

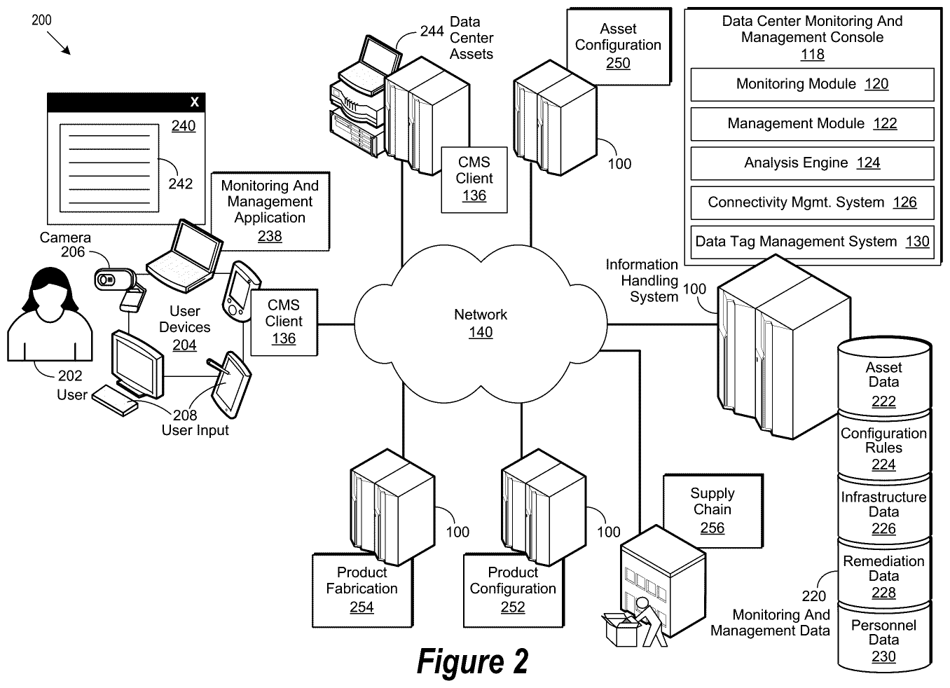

### DETAILED DESCRIPTION OF THE PREFERRED EMBODIMENTS

The embodiment of the present invention will hereinafter be described referring to drawings.

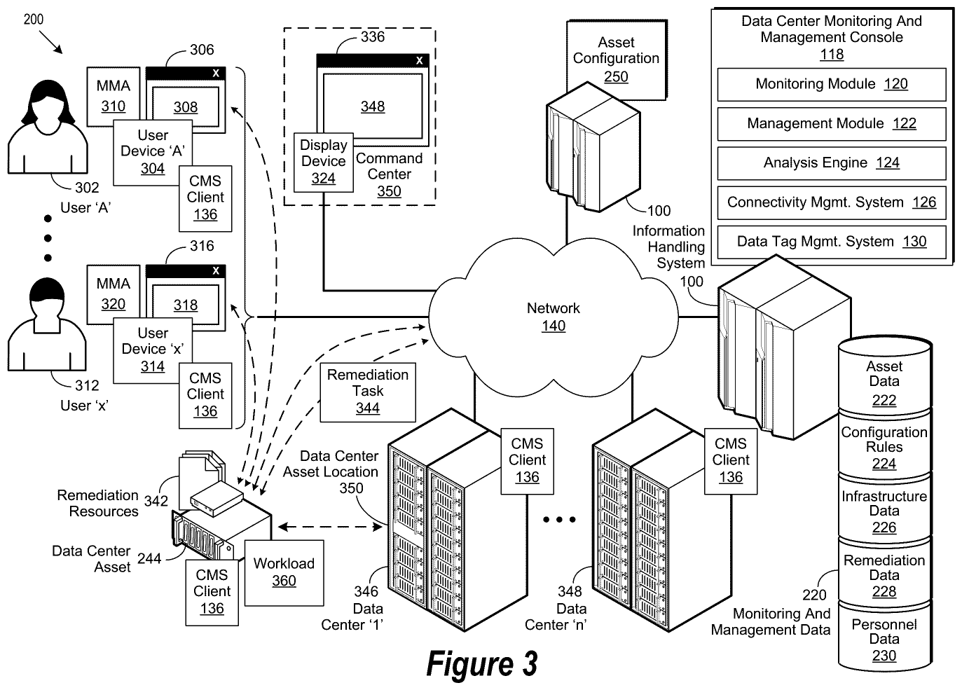

The outline of the etching processing procedure of the present example is shown in FIG. 3. The first step is to introduce an oxygen-containing gas in a vacuum container, generate plasma in a vacuum device by a plasma device to generate an oxygen radical or ozone and thus, form an oxide layer 5 on the surface of an SiCO film 1. The second step is to evacuate the oxygen-containing gas which has remained in a gas phase. The third step is to introduce a gas containing CF₄ and NH₃ into the vacuum container, generate plasma in the vacuum device by the plasma device to generate a reactive radical and thereby modify the oxide layer 5 into a layer (surface modified layer) 6 of a compound containing nitrogen, hydrogen, silicon, fluorine, carbon, and oxygen. The fourth step is to evacuate the gas which has remained in the gas phase. The fifth step is to add thermal energy to a wafer to thereby thermally decompose the surface modified layer 6 into a volatile molecule and eliminate the resulting molecule to etch the SiCO film 1. The sixth step subsequent thereto is to cool the wafer to a temperature at the time of surface oxidation. By repeating the first to six steps, the etching amount is controlled to a desired value in the end.

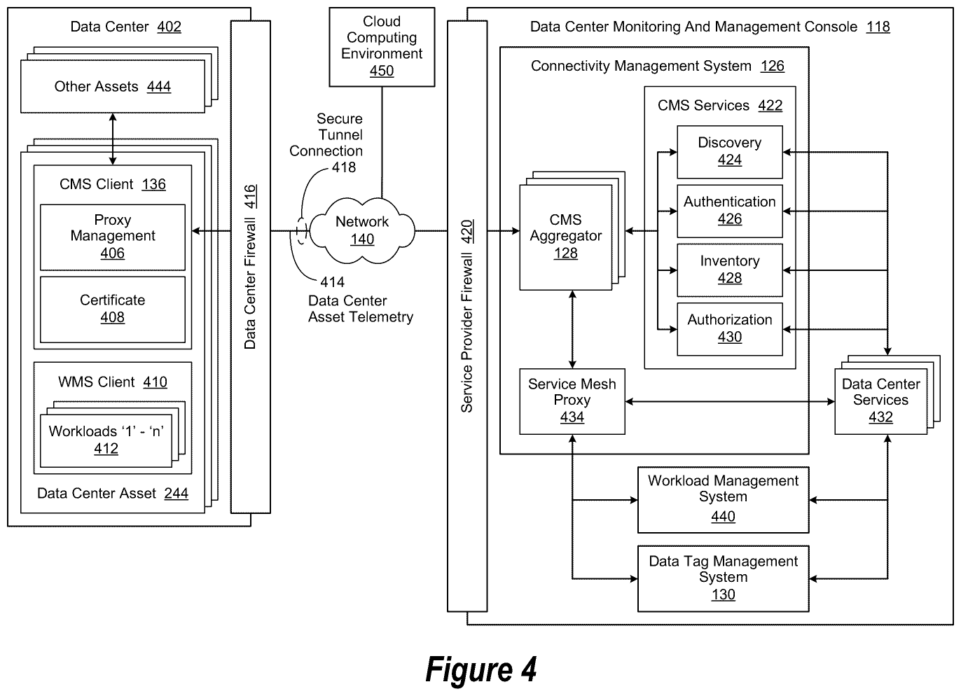

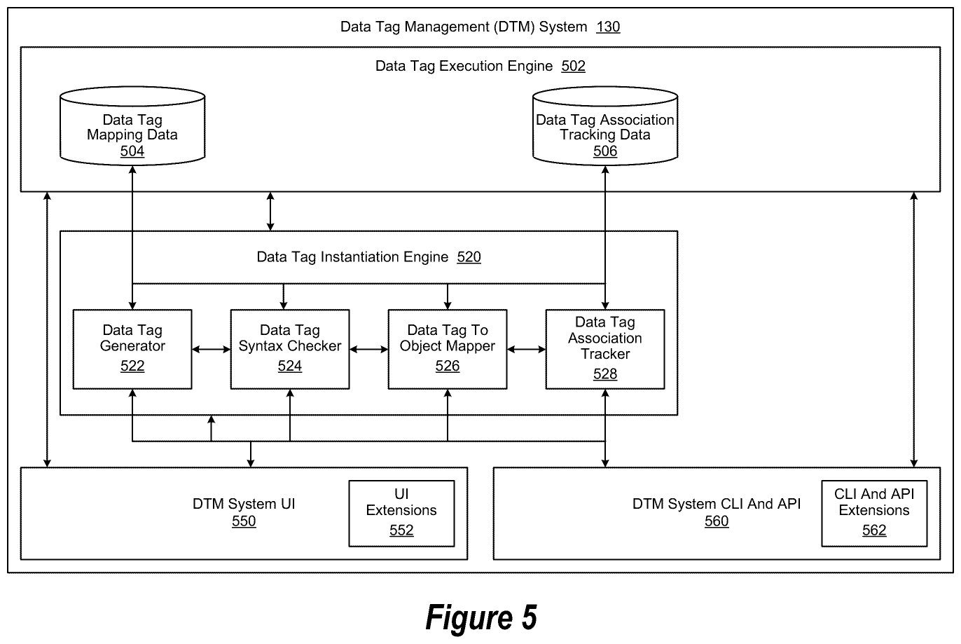

FIG. 4 shows the dependence of the etching amount of the SiCO film 1 on the number of cycles when the first to sixth steps are repeated. It shows the results with the surface oxidation step and without the step, respectively. It has been found from the drawing that with an increase in the number of cycles, the etching amount of the SiCO film increases. It has also been found that the etching amount has increased by about 8 times by the addition of the surface oxidation step. Next, FIG. 5 shows the dependence of an etching rate (etching amount per cycle) on the surface oxidation time. The surface modification time at this time is fixed to 150 seconds. It has been found that an increase in etching rate is saturated with an increase in the oxidation time, and the saturation time is 10 seconds. Further, FIG. 6 shows the dependence of the etching rate on the surface modification time. The surface oxidizing time at this time is fixed to 30 seconds. It has been found that an increase in etching rate is saturated with an increase in the surface modification time, and the saturation time is from about 30 seconds to 60 seconds.

These results shown in FIGS. 5 and 6 have verified that the etching process of the present Example is an atomic layer etching (ALE) process having self saturation (self-limiting) property. Using the present etching process makes it possible to achieve highly-precise control of an etching amount and uniform processing within the surface of the wafer and in the depth direction thereof, in isotropic dry etching of the SiCO film.

The outline of the entire constitution of the etching processing apparatus will next be described referring to FIG. 7. The processing chamber 7 is comprised of a base chamber (vacuum container) 11 which has therein a wafer stage 9 for placing a wafer 8 thereon. The processing chamber 7 has, thereabove, a plasma source (ICP plasma source) using an ICP (Inductively Coupled Plasma) discharge system. The ICP plasma source is used for the cleaning of the inner wall of the chamber with plasma or generation of a reactive gas by plasma.

The processing chamber 7 has, in the upper portion thereof, a cylindrical discharge tube 12 that constitutes the ICP plasma source and the discharge tube 12 has, outside thereof, an ICP coil 20. To the ICP coil 20, a high-frequency power source 21 for plasma formation is connected via a matching device 22. As the frequency of the high-frequency electricity of the high-frequency power source 21, a frequency band of dozens of MHz such as 13.56 MHz is used. The discharge tube 12 has thereabove a top plate 25. The top plate 25 has therebelow a gas dispersion plate 24 and a shower plate 23. A processing gas is introduced into the discharge tube 12 via the gas dispersion plate 24 and the shower plate 23. The discharge tube 12 and the high-frequency power source 21 constitute a plasma source.

The supply flow rate of the processing gas is adjusted by mass flow controllers 50 provided for respective gas types. The mass flow controllers 50 have, on the downstream side thereof, gas distributors 51, which supply a gas to the vicinity of the center of the discharge tube 12 and the outer periphery thereof, while controlling the flow rate or composition of the gases independently. By this, the space distribution of the partial pressure of the processing gas can be controlled in detail. FIG. 7 shows using examples of Ar, N₂, CHF₃, CF₄, SF₆, O₂, NF₃, HF, Cl₂, BCl₃, NH₃, H₂, CH₂F₂, CH₃F, CH₃OH as a processing gas, but another gas may also be usable.

The processing chamber 7 has an exhaust mechanism 15 connected to the bottom thereof via an evacuation piping 16 for reducing the pressure of the processing chamber 7. The exhaust mechanism 15 is, for example, comprised of a turbo-molecular pump, a mechanical booster pump, or a dry pump, but it is not limited to such one. In order to adjust the pressure of the processing chamber 7, a pressure control mechanism 14 is placed for the evacuation piping 16 connected to the exhaust mechanism 15.

The wafer stage 9 has, thereabove, an IR lamp unit for heating the wafer 8. The IR lamp unit is equipped with an IR lamp 60, a reflector 61 which reflects an IR light, and an IR light transmission window 72. Here, circle type (circular) IR lamps 60-1, 60-2, and 60-3 are used as the IR lamp 60 respectively.

The IR lamp 60 emits light (being called “IR light” herein) which is mainly light from a visible light region to an infrared light region. In this example, the three circles of IR lamps 60-1, 60-2, and 60-3 are concentrically placed, but they may be replaced by two circles or 4 circles or more. The IR lamps 60 have thereabove a reflector 61 for reflecting the IR light downward (wafer-placed direction).

To the IR lamps 60, an IR lamp power source 73 is connected and they have therebetween a high-frequency cut filter 74 to prevent the noise of the high-frequency electricity from entering the IR lamp power source 73. In addition, the IR lamp power source 73 has a function of independently controlling the electricity which is to be supplied to the IR lamps 60-1 to 60-3 and it is designed to adjust the diameter-direction distribution of the heating amount of the wafer 8 (wiring is partially omitted from the drawing).

IR lamp unit has, at the center thereof, a flow path 27. This flow path 27 has therein a slit plate 26 with a plurality of holes for blocking ions or electrons formed in the plasma and irradiating the wafer 8 with only a neutral gas or neutral radical which has passed through the holes.

The wafer stage 9 has therein a flow path 39 of a refrigerant for cooling the stage and it is designed to circulate and supply the refrigerant through the flow path 39 by a chiller 38. In order to fix the wafer 8 by electrostatic adsorption, the wafer stage has a plate-like electrode plate 30 buried therein and a DC power source 31 is connected thereto.

To efficiently cool the wafer 8, a helium (He) gas whose flow rate has been adjusted by the mass flow controller 55 can be supplied between the back surface of the wafer 8 and the wafer stage 9. In addition, the surface (where the wafer 8 is placed) of the wafer stage 9 is coated with a resin such as polyimide to prevent the back surface of the wafer from being damaged by heating/cooling while adsorbing the wafer 8 to the wafer stage. Further, the wafer stage 9 has therein a thermocouple 70 for measuring the temperature of the stage and this thermocouple is connected to a thermocouple thermometer 71.

The etching process of the present example will be described referring to FIG. 8. The sequence of FIG. 8 is controlled by a control unit 80 of the etching processing apparatus. The control unit 80 is connected to the power source, mechanism, and controller of the etching processing apparatus via a control wire 81 and it controls them so as to perform a predetermined sequence. After the wafer 8 is carried to the processing chamber 7 via a carrier port (omitted from the drawing) provided in the processing chamber 7, the wafer 8 is supplied with electricity from a DC power source 31 to fix it onto the wafer stage 9 by electrostatic adsorption and at the same time, the back surface of the wafer 8 is supplied with a wafer cooling He gas. The pressure of the He gas is, for example, 1 kPa or 2 kPa.

Then, the processing chamber 7 is supplied with an Ar gas for diluting an etching gas therewith via the mass flow controller 50, the gas distributor 51, and a shower plate 23. The flow rate of the Ar gas is, for example, 0.5 L, 1 L, or 2 L. The supply of the Ar gas for dilution is thereafter continued until the completion of the etching.

The first step includes introducing a gas containing an oxygen molecule into the processing chamber 7, turning the high-frequency power source 21 ON to form plasma in a discharge region 13, and generating an oxygen radical or ozone. For example, when an oxygen gas is used, the gas flow rate is, 0.5 L, 1 L, or 2 L. The electricity supplied to the high-frequency power source 21 is, for example, 1000 W, 1500 W, or 2000 W. The total pressure of the Ar gas for dilution and the oxygen gas is, for example, 50 Pa, 100 Pa, 200 Pa, or 300 Pa. These reactive species formed in the plasma are supplied to the processing chamber 7 via the flow path 27 and the slit plate 26 and adsorb to the surface of the wafer 8. These reactive species react with the surface of the SiCO film 1 to form an oxide layer 5 containing silicon, carbon, oxygen, and hydrogen on the surface of the SiCO film. Then, the high-frequency power source 21 is turned OFF to terminate the plasma formation and then terminate the supply of the reactive species.

The second step includes evacuating the gas containing the oxygen molecule which has remained in the gas phase to make provision for the gas supply in the third step.

The third step includes introducing a gas containing CF₄ molecule and NH₃ molecule in the processing chamber 7, turning the high-frequency power source 21 ON, forming plasma in the discharge region 13 and generating a reactive radical. The flow rate of the CF₄ gas is, for example, 0.05 L, 0.1 L, 0.2 L, or 0.3 L and that of the NH₃ gas is, for example, 0.1 L, 0.2 L, 0.3 L, 0.4 L, or 0.5 L. The total pressure of the dilution gas, CF₄ gas, and NH₃ gas is, for example, 50 Pa, 100 Pa, 200 Pa, or 300 Pa. The reactive radical generated in the plasma is supplied to the processing chamber 7 via the flow path 27 and slit plate 26 and adsorbs to the surface of the oxide layer 5. Due to a reaction between the reactive radical with the oxide layer 5, the oxide layer forms a layer (surface modified layer) 6 of a compound containing nitrogen, hydrogen, silicon, fluorine, carbon, and oxygen. In order to suppress the spontaneous advance of the formation and elimination of the surface modified layer 6, the surface temperature during radical irradiation is required to be kept at 80° C. or less. Then, the high-frequency power source 21 is turned OFF to terminate the plasma formation and terminate the supply of the reactive radical.

The fourth step includes evacuating the gas containing CF₄ molecule and NH₃ molecule which has remained in the gas phase and making provision for the next fifth step.

The fifth step includes heating the wafer with the IR lamps 60 and thereby thermally decomposing and eliminating the surface modified layer 6 formed on the film surface and then, etching (removing) the SiCO film 1. At this time, it is desired to adjust also the wafer temperature to 100° C. or more. In order to enhance the heating efficiency with the IR lamps 60, the supply of the He gas to the back surface of the wafer 8 is terminated in advance of the aforesaid processing. The maximum achieving temperature of the wafer temperature is desirably 350° C. or less to suppress a semiconductor device from being damaged by a thermal burden.

The sixth step includes supplying the back surface of the wafer 8 with a wafer cooling He gas to cool the wafer and returning the wafer temperature to the temperature of the wafer stage 9.

By repeating the first to sixth steps, the etching amount is controlled to a desired value in the end.

In the etching processing of the present Example, as described in FIGS. 5 and 6, an increase in the etching rate is saturated with an increase in the surface oxidation time and surface modification time so that uniform etching in the wafer surface and depth direction can be achieved.

In the present Example, an example of using IR lamps 60 for heating the wafer is shown, but a heating method is not limited thereto. For example, a method of heating the wafer stage or a method of transporting the wafer separately to a device used only for heating and subjecting it to a heating treatment.

The present invention is not limited to the aforesaid embodiment and it embraces various modification examples. For example, the aforesaid embodiment is described in detail for facilitating the understanding of the present invention and it does not necessarily have all the constitutions described above. A portion of the constitution in one embodiment may be replaced by a constitution of another embodiment or the constitution of one embodiment may have the constitution of another embodiment by addition. A portion of the constitution of each embodiment may be subjected to addition, deletion, or substitution with another constitution.

### REFERENCE SIGNS LIST

1: SiCO film
2: Si nanosheet
3: SiGe sacrificial layer
4: CMOS gate
5: oxide layer
6: surface modified layer
7: processing chamber
8: wafer
9: wafer stage
11: base chamber
12: discharge tube
13: discharge region
14: pressure control mechanism
15: exhaust mechanism
16: evacuation piping
20: ICP coil
21: high-frequency power source
22: matching device
23: shower plate
24: gas dispersion plate
25: top plate
26: slit plate
27: flow path
30: electrode plate
31: DC power source
38: chiller
39: flow path
50: mass flow controller
51: gas distributor
55: mass flow controller
60: IR lamp
61: reflector
70: thermocouple
71: thermocouple thermometer
72: IR light transmission window
73: IR lamp power source
74: high-frequency cut filter
80: control unit
81: control wire

What is claimed is:

1. An etching processing method for etching an SiCO film formed on a wafer, comprising:
a first step of supplying the wafer placed on a wafer stage in a processing chamber inside a vacuum container with an oxygen radical or ozone to oxidize a surface of the SiCO film,
a second step of supplying the wafer with reactive radical by using plasma to form a modified layer from an oxide layer on the surface of the SiCO film, and
a third step of heating the wafer to eliminate and remove the modified layer, wherein:
the first to third steps are performed in repetition.

2. The etching processing method according to claim 1, wherein the modified layer is formed on the surface of the SiCO film while supplying a helium gas between the wafer and the wafer stage.

3. The etching processing method according to claim 1, wherein the modified layer is a layer of a compound containing nitrogen, hydrogen, silicon, fluorine, oxygen, and carbon.

4. The etching processing method according to claim 1, wherein the reactive radical is formed by introducing a gas containing CF₄ and NH₃ into the vacuum container to generate plasma therein.

5. The etching processing method according to claim 1, wherein the wafer is heated by irradiating, from above the wafer, the wafer with light which is mainly light from a visible light region to an infrared light region.

6. An etching processing apparatus, comprising:
a vacuum container having therein a processing chamber and a plasma source provided above the processing chamber,
a wafer stage which is provided in the processing chamber and on which a wafer having an SiCO film formed thereon is placed,
a first mass flow controller that supplies the plasma source with a processing gas,
a heating device for heating the wafer, and
a control unit for controlling etching processing of the SiCO film, wherein:
the control unit conducts the following steps in repetition:
a step of introducing, into the plasma source, a gas containing an oxygen whose supply flow rate is adjusted by the first mass flow controller, causing the plasma source to generate plasma, supplying the wafer with an oxygen radical or ozone, and thereby oxidizing a surface of the SiCO film;
a step of introducing, into the plasma source, a gas containing CF₄ and NH₃ whose supply flow rate is adjusted by the first mass flow controller, causing the plasma source to generate plasma, supplying the wafer with the reactive radical thus generated, and thereby forming a modified layer on a surface of the SiCO film, and
a step of heating the wafer by the heating device to eliminate and remove the modified layer.

7. The etching processing apparatus according to claim 6, further comprising:
a second mass flow controller for supplying a helium gas between the wafer and the wafer stage, wherein:
in the step of forming the modified layer on the surface of the SiCO film, the control unit introduces, between the wafer and the wafer stage, the helium gas whose supply flow rate is adjusted by the second mass flow controller.

8. The etching processing apparatus according to claim 6, wherein the modified layer contains a compound containing nitrogen, hydrogen, silicon, fluorine, oxygen, and carbon.

9. The etching processing apparatus according to claim 6, wherein the heating device has a lamp for irradiating, from above the wafer, the wafer with light which is mainly light from a visible light region to an infrared light region.
